(19) United States
(12) Patent Application Publication
(10) Pub. No.: US 2015/0021172 A1
(43) Pub. Date: Jan. 22, 2015

(54) THIN FILM FORMING APPARATUS

(71) Applicant: NITTO DENKO CORPORATION, Osaka (JP)

(72) Inventors: Tomotake Nashiki, Osaka (JP); Akira Hamada, Osaka (JP)

(73) Assignee: NITTO DENKO CORPORATION, Osaka (JP)

(21) Appl. No.: 14/331,428

(22) Filed: Jul. 15, 2014

(30) Foreign Application Priority Data
Jul. 19, 2013 (JP) 2013-150916

(51) Int. Cl. H01J 37/32

(52) U.S. Cl. CPC H01J 37/32449
USPC 204/298.03

(57) ABSTRACT

A thin film forming apparatus includes: a gas supply device for supplying a gas for film deposition configured to include a plurality of gas supply sections arranged side by side in a width direction of a film substrate in a vacuum chamber, and a supply amount adjustment section for adjusting the supply amount of the gas for each of the gas supply sections; and a gas partial pressure measurement device for measuring partial pressure of each kind of gas in the vacuum chamber configured to include measurement sections disposed so as to correspond to a position where each of the gas supply sections is disposed in the width direction of the film substrate, and measure the partial pressure of the gas at a position where each of the measurement sections is disposed.

### BACKGROUND OF THE INVENTION

1. Field of the Invention

The present invention relates to a thin film forming apparatus, and particularly to a thin film forming apparatus which forms a thin film on a surface of a film substrate by a so-called roll-to-roll system using a sputtering method.

2. Description of Related Art

A roll-to-roll type thin film forming apparatus which continuously deposits a thin film on a surface of a film substrate running in a lengthwise direction in a process of rewinding the film substrate delivered from an unwinding roll formed by winding the long film substrate is used for production of various functional films in view of its high productivity.

Examples of the functional film include transparent conductive films obtained by depositing a thin film of indium-tin-oxide (ITO) on a polyethylene terephthalate (PET) film substrate. The transparent conductive film is indispensable for preparing transparent electrodes for touch panels, solar cells, liquid crystal displays, organic EL displays, and the like.

A conventional thin film forming apparatus for producing an ITO thin film on a film substrate by a sputtering method is generally configured as below.

That is, the thin film forming apparatus includes a film depositing roll which is stored in a vacuum chamber and wound with a part of a running film substrate, and a target material formed of an indium-tin sintered body is provided so as to face the film depositing roll with the film substrate interposed therebetween.

An argon gas as an inert gas for inducing sputtering and oxygen as a reactive gas to be provided for deposition of an ITO thin film are introduced into the vacuum chamber.

Argon ionized by applying a high voltage between the film depositing roll wound with a part of the running film substrate and the target material (indium-tin sintered body) strikes the indium-tin sintered body, and atoms of indium and tin on the surface of the target material are thereby sputtered, and react with oxygen to deposit on the surface of the film substrate, so that an ITO thin film is formed.

For further improvement of productivity in a thin film forming apparatus, the film width of a long film substrate tends to be increased, and in this case, such a phenomenon is recognized that variations in thickness of an ITO thin film to be formed and electric resistance value thereof in a width direction become larger as compared to a case where the film width is smaller.

With further improvement of performance of applied equipment such as a touch panel, in recent years, still higher quality is desired with regard to the thickness and electric resistance value of an ITO thin film in a transparent conductive film.

The above-mentioned problems associated with an increase in film width of long film substrates occur not only in production of transparent conductive films but also in production of other functional films.

### SUMMARY OF THE INVENTION

It is an object of the present invention to provide a thin film forming apparatus capable of more reliably suppressing variations in quality of the formed thin film in a width direction of a long film substrate as compared to conventional apparatuses.

To achieve the object described above, in a first preferred aspect of the present invention, there is provided a thin film forming apparatus according to the present invention configured to continuously deposit a thin film on a surface of a long film substrate that is delivered from an unwinding roll formed by winding the long film substrate and is running in a lengthwise direction using a sputtering method, the thin film forming apparatus including: a vacuum chamber; a film depositing roll stored in the vacuum chamber and wound with a part of the running film substrate on an outer circumferential surface; a target material disposed so as to face the film depositing roll on an outside in a radial direction of the film depositing roll at a winding position of the long film substrate; a gas supply device for supplying a gas for the film deposition into the vacuum chamber; and a gas partial pressure measurement device for measuring a partial pressure of each kind of gas in the vacuum chamber, in which the gas supply device includes a plurality of gas supply sections arranged side by side in a width direction of the long film substrate in the vacuum chamber and a supply amount adjustment section capable of adjusting a supply amount of the gas for each of the gas supply sections, and the gas partial pressure measurement device includes a plurality of measurement sections arranged side by side in the width direction of the long film substrate, and a partial pressure of the gas is measured at a position where each of the measurement sections is disposed.

In a second preferred aspect of the thin film forming apparatus according to the present invention, each of the measurement sections is disposed so as to correspond to a position where each of the gas supply sections is disposed.

In a third preferred aspect of the thin film forming apparatus according to the present invention, the gas is a reactive gas provided for the film deposition.

In a fourth preferred aspect of the thin film forming apparatus according to the present invention, the gas is an inert gas for inducing sputtering.

In a fifth preferred aspect of the thin film forming apparatus according to the present invention, the gas is a mixed gas containing an inert gas for inducing sputtering and a reactive gas provided for the film deposition.

In a sixth preferred aspect of the thin film forming apparatus according to the present invention, the gas partial pressure measurement device is a quadrupole mass spectrometer.

### Advantages of the Invention

According to a thin film forming apparatus having the configuration described above, since the supply amount of a gas can be adjusted for each of the gas supply sections based on the measurement result of a gas partial pressure measured in a measurement section corresponding to each of the plurality of gas supply sections arranged side by side in the width direction of the long film substrate, unevenness in the gas partial pressure in the width direction can be suppressed as much as possible. Therefore, variations in quality of the formed thin film in the width direction, caused by the unevenness in gas partial pressure, can be suppressed more reliably as compared to conventional thin film forming apparatuses having only one supply section in a width direction.

For a full understanding of the present invention, reference should now be made to the following detailed description of the preferred embodiments of the invention as illustrated in the accompanying drawings.

### BRIEF DESCRIPTION OF THE DRAWINGS

FIG. 1 is a lateral sectional view illustrating a schematic configuration of a thin film forming apparatus according to an embodiment of the present invention;

FIG. 2 is a part of a longitudinal sectional view with the thin film forming apparatus cut along A-A line in FIG. 1; and

FIG. 3 is a perspective view illustrating a schematic configuration of a gas supply unit in the thin film forming apparatus.

### DESCRIPTION OF THE PREFERRED EMBODIMENTS

An embodiment of a thin film forming apparatus according to the present invention will now be described below with reference to the drawings. In this embodiment, a case will be described as an example where a PET film substrate is used as a long film substrate, and an ITO thin film is formed on a surface of the PET film substrate to prepare a transparent conductive film.

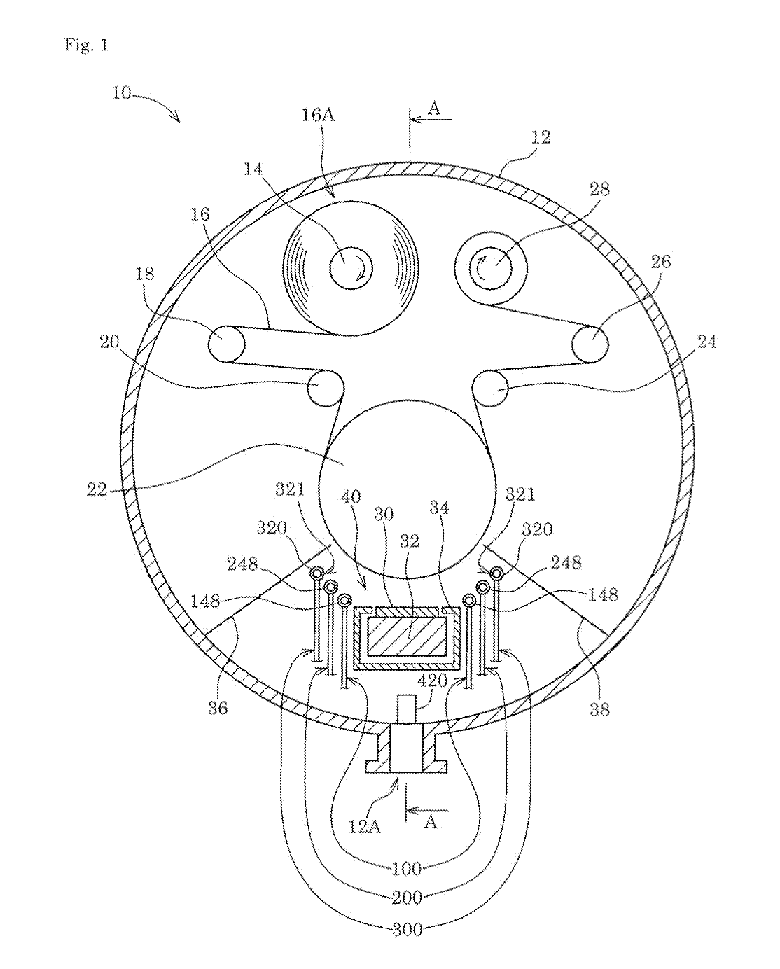

As illustrated in FIG. 1, a thin film forming apparatus 10 according to the embodiment includes a vacuum chamber 12 having an exhaust port 12A to which a vacuum pump (not illustrated) is connected.

An unwinding shaft 14 is provided in the vacuum chamber 12. As illustrated in FIG. 1, a PET film substrate 16 delivered from an unwinding roll 16A formed by winding a PET film substrate 16 around an unwinding shaft 14 is sequentially hung and passed over a first guide roll 18, a second guide roll 20, a film depositing roll 22, a third guide roll 24 and a fourth guide roll 26, and wound around a wind-up shaft 28. For example, the PET film substrate 16 has a width of 1600 mm and a total length of 5000 m.

Over a range extending from the unwinding shaft 14 to the wind-up shaft 28, an ITO thin film is continuously deposited on a surface, opposite to the film depositing roll 22, of the PET film substrate 16 partially wound around the outer circumferential surface of the film depositing roll 22 and is running in a lengthwise direction using a sputtering method in the manner described later. The running speed of the PET film substrate 16 can be changed by controlling the revolution speed of a motor (not illustrated) that rotatively drives the unwinding shaft 14 and a motor (not illustrated) that rotatively drives the wind-up shaft 28.

The film depositing roll 22 is a known film depositing roll having a temperature control function, and the surface of the film depositing roll 22 is controlled to have a temperature suitable for film deposition.

A target material 30 is disposed so as to face the film depositing roll 22 on the outside in a radial direction of the film depositing roll 22 at a winding position of the PET film substrate 16 on the film depositing roll 22. In this example, the target material 30 is made of an indium-tin sintered body. The target material 30 is fixed on a cathode 32 by a screw (not illustrated). The cathode 32 is stored in a case 34.

Further, there are provided a reactive gas supply device 100 for supplying a reactive gas (oxygen in this example), which is supplied for deposition of an ITO thin film, to an opposing region between the film depositing roll 22 and the target material 30; an inert gas supply device 200 for supplying the opposing region with an inert gas (argon gas in this example) for inducing sputtering; and a vapor supply device 300 for supplying water vapor for adjusting the water content of the PET film substrate 16. A part of each supply device is illustrated in FIG. 1.

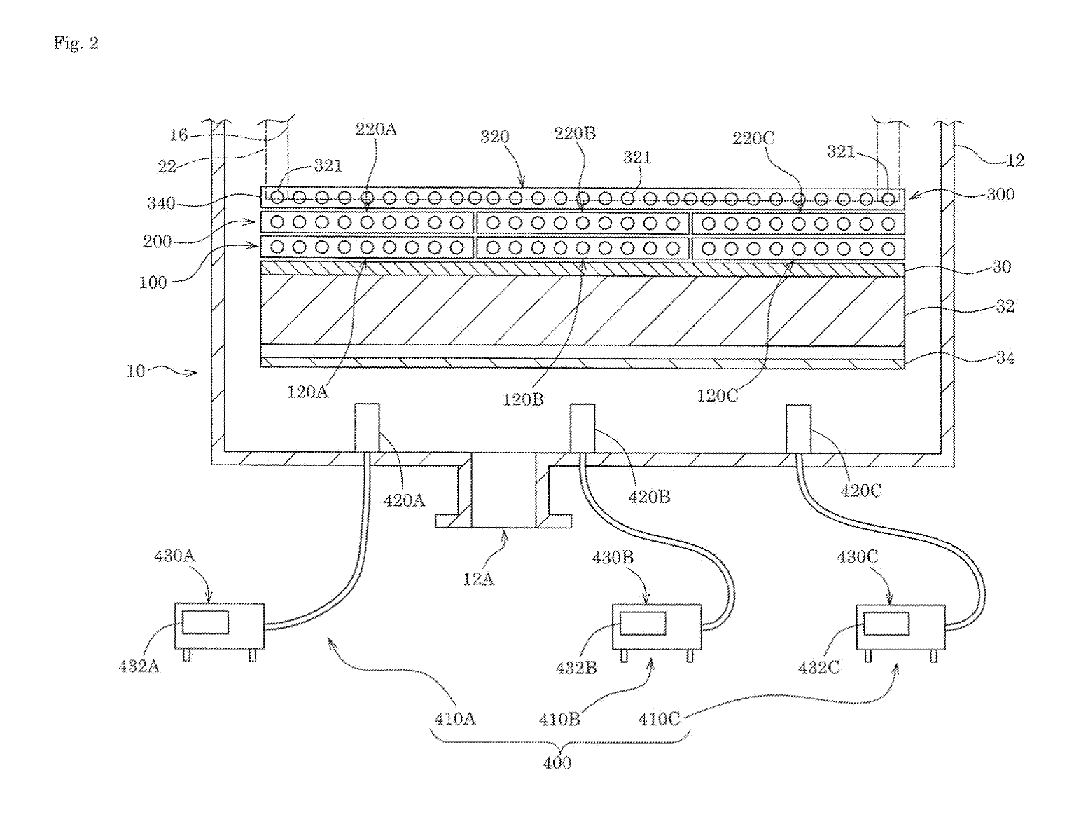

The supply devices 100, 200, and 300 will be now described with reference to FIG. 2. The supply devices 100, 200, and 300 each have an introduction pipe for introducing various kinds of gases or water vapor from the outside to the inside of the vacuum chamber 12, however, FIG. 2 illustrates only a supply section that finally supplies various kinds of gases or water vapor into the vacuum chamber 12 in each of the introduction pipes. In FIG. 2, the PET film substrate 16 and the film depositing roll 22 are illustrated with a dashed line for the sake of convenience.

The vapor supply device 300 (FIG. 1) has a vapor generator (not illustrated) provided outside the vacuum chamber 12, and vapor from the vapor generator is introduced through an introduction pipe (partially not illustrated) from the outside of the vacuum chamber 12 to the inside of the vacuum chamber 12, and water vapor is appropriately supplied from a supply section 320 illustrated in FIG. 2. The supply section 320 has a plurality of supply holes 321 provided in an introduction pipe portion 340 arranged in an axial center direction of the film depositing roll 22, i.e., in a width direction of the PET film substrate 16, and discharges water vapor from each of the supply holes 321. A pair of supply sections 320 are provided such that the supply holes 321 of both the supply sections 320 face each other with the target material 30 interposed therebetween as illustrated in FIG. 1.

Returning to FIG. 2, the reactive gas supply device 100 has a plurality of (three in this example) supply sections 120A, 120B, and 120C arranged side by side at equal intervals in the width direction of the PET film substrate 16.

The inert gas supply device 200 also has a plurality of (three in this example) supply sections 220A, 220B, and 220C arranged side by side at equal intervals in the width direction of the PET film substrate 16.

Each of the supply sections 120A, 120B, and 120C of the reactive gas supply device 100 and the supply sections 220A, 220B, and 220C of the inert gas supply device 200 is a part of total six gas supply units provided independently.

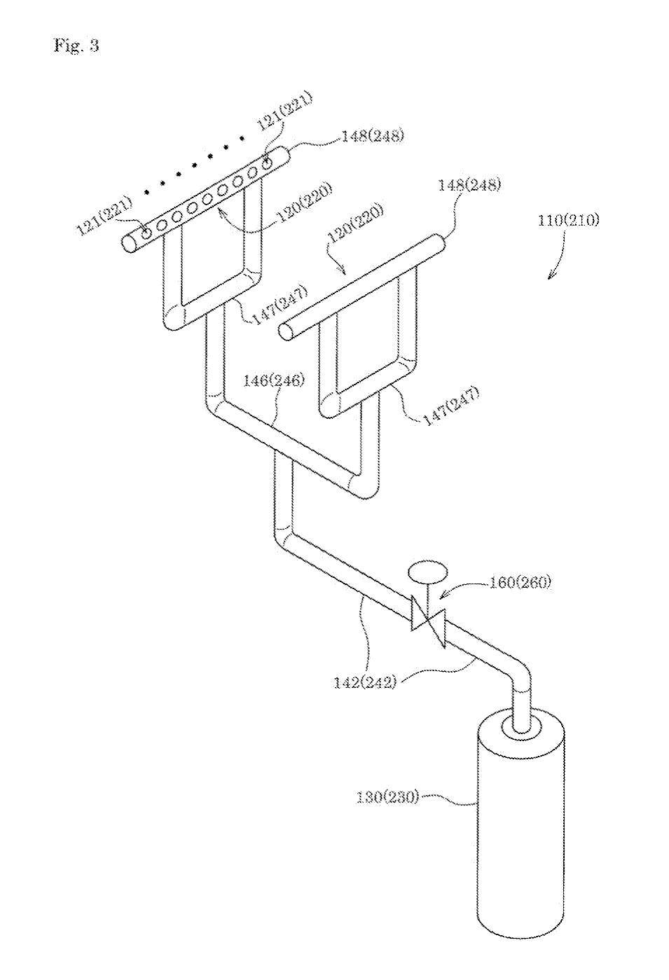

The gas supply unit will now be described with reference to FIG. 3. Since the six gas supply units each basically have the same configuration, alphabetical symbols are omitted, and a part corresponding to a gas supply unit constituting the reactive gas supply device 100 is given a reference numeral in the 100s and a part corresponding to a gas supply unit constituting the inert gas supply device 200 is given a reference numeral in the 200s.

The gas supply unit 110 (210) has a gas cylinder 130 (230). The gas cylinder 130 is filled with oxygen, and the gas cylinder 230 is filled with an argon gas.

One end part of a first introduction pipe 142 (242) curved in the shape of a hook is connected to the gas cylinder 130 (230). A valve 160 (260) is connected to a midpoint of the first introduction pipe 142 (242).

The other end part of the first introduction pipe 142 (242) is connected to the central part of a U-shaped second introduction pipe 146 (246) in a lengthwise direction.

Both end parts of the second introduction pipe 146 (246) are connected to the central parts of a pair of U-shaped third introduction pipes 147 (247) in a lengthwise direction, respectively.

Each of the pair of third introduction pipes 147 (247) is connected to each of a pair of straight-shaped fourth introduction pipes 148 (248). The connection position is a position where the distances from the central part of the fourth introduction pipe 148 (248) to both end parts of the third introduction pipe 147 (247) are equal to each other. The fourth introduction pipe 148 (248) is identical to the supply section 120 (220). The pair of fourth introduction pipes 148 (248) are provided in parallel to each other.

In each of the fourth introduction pipes 148 (248), a plurality of supply holes 121 (221) are provided side by side in a lengthwise direction (supply holes 121 (221) provided in the closest fourth introduction pipe 148 (248) are not shown in FIG. 3).

The pair of fourth introduction pipes 148 (248) are provided at a position where an opposing region thereof is located in the vicinity of an upper surface of the target material 30 (opposing region between the target material 30 and the film depositing roll 22) (FIG. 1).

In the gas supply unit 110 (210), the gas cylinder 130 (230) is disposed outside the vacuum chamber 12, and the first introduction pipe 142 (242) extends through the vacuum chamber 12 while the vacuum chamber 12 is kept airtight (through part is not illustrated). The valve 160 (260) provided in the first introduction pipe 142 (242) exists on the outside of the vacuum chamber 12.

In the gas supply unit 110 (210) having the configuration described above, a gas filled in the gas cylinder 130 (230) is supplied through the first introduction pipe 142 (242), the second introduction pipe 146 (246), the third introduction pipe 147 (247), and the fourth introduction pipe 148 (248) to an opposing region between the target material 30 and the film depositing roll 22 in the vacuum chamber 12. The amount of a supplied gas is adjusted by adjusting the aperture of the valve 160 (260). That is, the valve 160 (260) serves as a gas supply amount adjustment section.

The reactive gas supply device 100 and the inert gas supply device 200 each have a plurality of (three in this example) gas supply units 110 and 210, and the supply sections 120A, 120B, and 120C and the supply sections 220A, 220B, and 220C are arranged side by side in the width direction of the PET film substrate 16 as illustrated in FIG. 2. Therefore, the introduction amount of the gas in the width direction can be adjusted by adjusting the flow rate of the introduced gas for each of the gas supply units 110 and 210.

Further, in each gas supply unit 110 (210), the lengths of conduits (gas passages) from the gas cylinder 130 (230) to both ends of each of the third introduction pipes 147 (247) are equal to each other, and the third introduction pipe 147 (247) is connected to the fourth introduction pipe 148 (248) at a position where the distances from the central part of the fourth introduction pipe 148 (248) to both ends of the third introduction pipe 147 (247) are equal to each other, as illustrated in FIG. 3. Therefore, for example, as compared to a case where the third introduction pipe 147 (247) is eliminated and both end parts of the second introduction pipe 146 (246) are each (extended and) connected directly to the fourth introduction pipe 148 (248), the flow rate of a gas flowing out of each of the plurality of supply holes 121 (221) can be made more uniform, and thus the partial pressure distribution of the gas in a lengthwise direction of the supply section 120 (220) (width direction of the PET film substrate 16) becomes more uniform.

The thin film forming apparatus 10 has a gas partial pressure measurement device 400 as illustrated in FIG. 2.

The gas partial pressure measurement device 400 includes three gas partial pressure analyzers 410A, 410B, and 410C.

The gas partial pressure analyzers 410A, 410B, and 410C are the same partial pressure analyzer, and for example, MICROPOLE System (QL-SG01-1A, QL-MC01-1A), a quadrupole mass spectrometer manufactured by HORIBA, Ltd., can be used.

Since the gas partial pressure analyzers 410A, 410B, and 410C are the same, alphabetic symbols (A, B, C) given in the figure are omitted in the description when they do not have to be discriminated from one another.

The gas partial pressure analyzer 410 has a sensor 420 as a measurement section and a main body 430. The gas partial pressure analyzer 410 measures partial pressures of various kinds of gases at a detection position in the vacuum chamber 12 for each kind of gas based on detection results of the sensor 420. Measurement results are displayed on a monitor screen 432 of the main body 430. In this example, partial pressures of an argon gas, oxygen, and water vapor (H₂O gas) are displayed.

A sensor 420A, a sensor 420B, and a sensor 420C are each attached to the inner wall of the vacuum chamber 12.

The sensor 420A, the sensor 420B, and the sensor 420C are provided so as to correspond to positions where the supply sections 120A and 220A, the supply sections 120B and 220B, and the supply sections 120C and 220C are disposed, respectively, in the width direction of the PET film substrate 16. More specifically, in the width direction of the PET film substrate 16, the sensor 420A is disposed at a position corresponding to the center of the supply sections 120A and 220A, the sensor 420B is disposed at a position corresponding to the center of the supply sections 120B and 220B, and the sensor 420C is disposed at a position corresponding to the center of the supply sections 120C and 220C.

Returning to FIG. 1, the inside of the vacuum chamber 12 is partitioned in a circumferential direction by two partition walls 36 and 38 provided in the radial direction of the film depositing roll 22 at a slight distance from the outer circumferential surface of the film depositing roll 22, and a film deposition chamber 40 is formed by the outer circumferential surface part of the film depositing roll 22, the partition walls 36 and 38, and the inner wall surface part of the vacuum chamber 12.

In the thin film forming apparatus 10 having the configuration described above, the inside of the vacuum chamber 12 is decompressed by a vacuum pump (not illustrated), the unwinding shaft 14 and the wind-up shaft 28 are rotatively driven to cause the PET film substrate 16 to run in the lengthwise direction thereof, oxygen is supplied by the reactive gas supply device 100, an argon gas is supplied by the inert gas supply device 200, and a voltage is applied between the cathode 32 and the film depositing roll 22 to generate glow discharge therebetween, so that argon is ionized, and the ionized argon strikes a target. Atoms of indium and tin on the surface of the struck target material are sputtered, and react with oxygen to deposit on the surface of the PET film substrate 16, so that an ITO thin film is formed.

In this case, as the concentration of an argon gas becomes higher (i.e., the partial pressure of an argon gas becomes higher), the amount of atoms of indium and tin jumping out of the target material increases, and therefore the thickness of the ITO thin film increases. Conversely, as the partial pressure of an argon gas becomes lower, the thickness of the ITO thin film decreases. An argon gas partial pressure at which a desired thickness is obtained (hereinafter, referred to as a “reference argon gas partial pressure”) is determined beforehand.

The value of the oxygen concentration (i.e., oxygen partial pressure) has influences on the electric resistance value of the ITO thin film to be formed. A proper value of an oxygen partial pressure at which the electric resistance value becomes the lowest (hereinafter, referred to as a “reference oxygen partial pressure) is determined beforehand, and irrespective of whether the oxygen partial pressure is higher or lower than the reference oxygen partial pressure, the electric resistance value is greater than an electric resistance value obtained when film deposition is performed at the reference oxygen partial pressure.

As the width of the PET film substrate on which an ITO thin film is to be formed becomes greater, uniformity of the argon gas partial pressure and the oxygen partial pressure in the width direction of the film is reduced because the argon gas and oxygen need to be extensively supplied. As a result, thickness unevenness and unevenness in electric resistance value occur in the width direction of the film in the formed ITO thin film.

In this embodiment, in the vacuum chamber 12, the supply sections 220A, 220B, and 220C for an argon gas are arranged side by side in a film width direction of the PET film substrate 16, and the sensors 420A, 420B, and 420C of the gas partial pressure analyzers 410A, 410B, and 410C are each provided so as to correspond to a position where each of the supply sections 220A, 220B, and 220C is disposed in the film width direction.

In other words, the gas partial pressure measurement device 400 is configured to include the sensors 420A, 420B, and 420C as measurement sections each disposed so as to correspond to the position where each of the supply sections 220A, 220B, and 220C is disposed in the width direction of the PET film substrate 16, and measure partial pressures of various kinds of gases at the position where each of the sensors 420A, 420B, and 420C as the measurement sections is disposed.

Thus, each of measurement results of argon gas partial pressures measured by the gas partial pressure analyzers 410A, 410B, and 410C is compared with the reference argon gas partial pressure, and when there is any gas partial pressure analyzer for which the measurement result is below the reference argon gas partial pressure, the valve 260 of the gas supply unit 210 having a supply section (220A, 220B, 220C) corresponding to the position where the gas partial pressure analyzer (sensor) is disposed is moderately opened by an operator to increase the supply amount of an argon gas from the supply section. Conversely, when there is any gas partial pressure analyzer for which the measurement result exceeds the reference argon gas partial pressure, the valve 260 of the gas supply unit 210 having a supply section (220A, 220B, 220C) corresponding to the position where the gas partial pressure analyzer (sensor) is disposed is moderately closed by the operator to decrease the supply amount of an argon gas from the supply section.

Consequently, the distribution of the argon gas partial pressure in the film width direction can be made as uniform as possible, so that unevenness in thickness of the formed ITO thin film can be suppressed as much as possible.

Similarly, each of measurement results of oxygen gas partial pressures measured by the gas partial pressure analyzers 410A, 410B, and 410C is compared with the reference oxygen gas partial pressure, and when there is any gas partial pressure analyzer for which the measurement result is below the reference oxygen gas partial pressure, the valve 160 of the gas supply unit 110 having a supply section (120A, 120B, 120C) corresponding to the position where the gas partial pressure analyzer (sensor) is disposed is moderately opened by the operator to increase the supply amount of an argon gas from the supply section. Conversely, when there is any gas partial pressure analyzer for which the measurement result exceeds the reference oxygen gas partial pressure, the valve 160 of the gas supply unit 110 having a supply section (120A, 120B, 120C) corresponding to the position where the gas partial pressure analyzer (sensor) is disposed is moderately closed by the operator to decrease the supply amount of an oxygen gas from the supply section.

Consequently, the distribution of the oxygen gas partial pressure in the film width direction can be made as uniform as possible, so that unevenness in electric resistance value of the formed ITO thin film can be suppressed as much as possible.

The following operation may be performed based on measurement results of vapor (H₂O gas) partial pressures measured by gas partial pressure analyzers 410A, 410B, and 410C.

When an average of measurement results from three gas partial pressure analyzers 410A, 410B, and 410C is below the reference vapor partial pressure, the supply of water vapor by the vapor supply device 300 is moderately increased.

On the other hand, when an average of measurement results from three gas partial pressure analyzers 410A, 410B, and 410C exceeds the reference vapor partial pressure, the supply of water vapor by the vapor supply device 300 is stopped, and the temperature of the surface of the film depositing roll 22 is moderately increased.

By the above-described operation, the water content of the PET film substrate 16 can be adjusted to a proper value, and therefore when the ITO thin film formed by the thin film forming apparatus 10 is crystallized in the subsequent step, the time required for crystallization can be made as optimum as possible.

While the thin film forming apparatus according to the present invention has been described above based on the embodiment, the present invention is not limited to the aforementioned embodiment as a matter of course, and may include, for example, the following embodiments:

(1) In the aforementioned example, the thin film forming apparatus 10 has one film deposition chamber 40, however, a plurality of film deposition chambers may be formed (i.e., a partition wall may be further provided to partition the space in the vacuum chamber 12 in the circumferential direction of the film depositing roll 22), and a target material and the like may be provided in each film deposition chamber to form thin films at a plurality of sites in the lengthwise direction of a film substrate wound around the outer periphery of one film depositing roll (in the circumferential direction of the film depositing roll).

(2) In the aforementioned example, while main bodies 430A, 430B, and 430C are provided for sensors 420A, 420B, and 420C, respectively, the present invention is not limited thereto, and the sensors 420A, 420B, and 420C may be connected to one main body to display a measurement result from each of the sensors 420A, 420B, and 420C on the main body.

(3) In the aforementioned example, in the reactive gas supply device 100, while the gas cylinder 130 is provided for each of supply sections 120A, 120B, and 120C, and one gas cylinder and one supply section are connected on a one-to-one basis by a dedicated introduction pipe, the present invention is not limited thereto, and one gas cylinder may be provided, the introduction pipe may be branched in a three way, and a supply section may be formed at a terminal part of each of the branched introduction pipes. In this case, a valve is provided in each of the branched introduction pipes, so that the supply amount of a gas from each supply section can be independently adjusted.

A change may also be made to the above-described configuration in the inert gas supply device 200.

(4) In the aforementioned example, in the thin film forming apparatus 10, while an ITO thin film is formed on the surface of the PET film substrate, the thin film to be formed is not limited thereto. For example, niobium (Nb) as a metal target material, an argon gas as an inert gas and oxygen as a reactive gas may be used to form a thin film of niobium oxide (Nb₂O₅) on the surface of the PET film substrate.

(5) The long film substrate is not limited to a PET film, and single film substrates or laminated film substrates made of various kinds of plastics (homopolymers or copolymers) such as polyester, polyamide, polyvinyl chloride, polycarbonate, polystyrene, polypropylene, and polyethylene are used.

The target material is not limited to the material described above, and those that are formed into a metal compound thin film having transparent conductivity, for example, a metal oxide thin film and a metal nitride thin film, as a transparent conductive thin film by reactive sputtering film deposition, such as Sn, In, Cd, Zn, Ti, an alloy of In and Sb, and an alloy of In and Al can be widely used.

Examples of the transparent conductive thin film that is deposited by reactive sputtering on the surface of a long film substrate using such a metal target material include metal compound thin films such as metal oxide thin films such as those of ITO as well as SnO₂, In₂O₃, CdO, ZnO, In₂O₃ with Sb, and In₂O₃ with Al (usually referred to as ATO), and metal nitride thin films such as TiN and ZrN.

Examples of the inert gas for inducing sputtering include not only Ar but also He, Ne, Kr, and Xe, and these gases may be used alone, or may be used in mixture. Examples of the reactive gas to be provided for film deposition include oxygen in the case of depositing a metal oxide thin film, and nitrogen in the case of depositing a metal nitride thin film, these gases may be appropriately mixed and used, and besides these gases, other gases such as a nitrous oxide gas may be used.

(6) In the aforementioned embodiment, while an inert gas (Ar) and a reactive gas (oxygen) are supplied using separate gas supply units 110 and 210, the present invention is not limited thereto, and these gases may be supplied using a single gas supply unit. That is, one gas cylinder may be filled with a mixed gas including an inert gas and a reactive gas to supply the gas. For example, when an argon (Ar) gas and oxygen (O₂) are used for depositing an ITO thin film, a mixed gas having an argon gas: oxygen ratio of 80%:20% by volume is used.

(7) In the aforementioned example, while one kind of reactive gas is used, the present invention may also be applied to a case where two kinds of reactive gases are used. For example, when a thin film made of an oxynitride is formed, oxygen and nitrogen are simultaneously introduced into a vacuum chamber as a reactive gas. In this case, a thin film can be formed using a target material made of Si (which may be a metal or an oxide) and a PET film substrate or PC (polycarbonate) film substrate as a long film substrate.

(8) As a matter of course, the present invention may also be applied to a case where a reactive gas is not used, and a thin film of copper may be formed on a surface of a film substrate using, for example, a PET film substrate or a polyimide film substrate as a long film substrate and pure copper as a target material.

This application claims priority from Japanese Patent Application No. 2013-150916, which is incorporated herein by reference.

There has thus been shown and described a novel thin film forming apparatus which fulfills all the objects and advantages sought therefor. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A thin film forming apparatus configured to continuously deposit a thin film on a surface of a long film substrate that is delivered from an unwinding roll formed by winding the long film substrate and is running in a lengthwise direction using a sputtering method, the thin film forming apparatus, comprising:
a vacuum chamber;
a film depositing roll stored in the vacuum chamber and wound with a part of the running film substrate on an outer circumferential surface;
a target material disposed so as to face the film depositing roll on an outside in a radial direction of the film depositing roll at a winding position of the long film substrate;
a gas supply device for supplying a gas for the film deposition into the vacuum chamber; and
a gas partial pressure measurement device for measuring a partial pressure of each kind of gas in the vacuum chamber,
wherein the gas supply device includes a plurality of gas supply sections arranged side by side in a width direction of the long film substrate in the vacuum chamber and a supply amount adjustment section capable of adjusting a supply amount of the gas for each of the gas supply sections, and
the gas partial pressure measurement device includes a plurality of measurement sections arranged side by side in the width direction of the long film substrate, and a partial pressure of the gas is measured at a position where each of the measurement sections is disposed.

2. The thin film forming apparatus according to claim 1, wherein each of the measurement sections is disposed so as to correspond to a position where each of the gas supply sections is disposed.

3. The thin film forming apparatus according to claim 2, wherein the gas is a reactive gas provided for the film deposition.

4. The thin film forming apparatus according to claim 3, wherein the gas partial pressure measurement device is a quadrupole mass spectrometer.

5. The thin film forming apparatus according to claim 1, wherein the gas is a reactive gas provided for the film deposition.

6. The thin film forming apparatus according to claim 1, wherein the gas is an inert gas for inducing sputtering.

7. The thin film forming apparatus according to claim 1, wherein the gas is a mixed gas including an inert gas for inducing sputtering and a reactive gas provided for the film deposition.

8. The thin film forming apparatus according to claim 1, wherein the gas partial pressure measurement device is a quadrupole mass spectrometer.
